(19) United States
(12) Patent Application Publication
(10) Pub. No.: US 2005/0199187 A1
(43) Pub. Date: Sep. 15, 2005

(54) Heat treatment apparatus and substrate processing apparatus

(75) Inventors: Toyohide Hayashi, Horikawa-dori (JP); Masaki Nishida, Horikawa-dori (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/080,770

(22) Filed: Mar. 15, 2005

(30) Foreign Application Priority Data
Mar. 15, 2004 (JP) 2004-72748

(51) Int. Cl. C23C 16/00

(52) U.S. Cl. 118/725

(57) ABSTRACT

Seven gas ejection ports are provided in an upper surface of a transport arm, and are connected to gas supply piping. The gas supply piping is connected through a valve to a nitrogen gas supply unit. When the valve is opened with a substrate held on the transport arm, nitrogen gas is supplied from the nitrogen gas supply unit and ejected toward the entire space between the substrate held by the transport arm and the transport arm. Supplying the nitrogen gas to the space between the substrate and the transport arm prior to the loading of the substrate into a chamber causes the ambient atmosphere in the space to be replaced with the nitrogen gas. The transport arm is prevented from bringing the ambient atmosphere into the chamber, whereby the increase in oxygen concentration within the chamber is reliably inhibited. This provides a heat treatment apparatus capable of reliably inhibiting the increase in oxygen concentration within the chamber.

### BACKGROUND OF THE INVENTION

1. Field of the Invention

The present invention relates to a heat treatment apparatus for heat-treating a semiconductor substrate, a glass substrate for a liquid crystal display, a glass substrate for a photomask, a substrate for an optical disk and the like (referred to hereinafter as “substrates”) which are coated with a processing solution of a low-dielectric-constant material and the like to form a predetermined film such as an interlayer insulation film on the substrates, and a substrate processing apparatus having the heat treatment apparatus incorporated therein.

2. Description of the Background Art

Conventionally, circuit patterns formed on the substrates have multi-layer interconnections, and it is important that an interlayer insulation film between the multilayer interconnections has a flatness and an insulating property (or a low dielectric constant). Such an interlayer insulation film is formed by coating a substrate with a low-dielectric-constant material such as SOD (Spin-on-Dielectric) or polyimides and then firing the substrate by heat treatment.

An interlayer insulation film has been conventionally formed from a polyimide coating, for example, by a method to be described below. First, a spinning-type coating apparatus (a spin coater) or the like is used to uniformly coat a substrate with a processing solution of a polyimide. The substrate coated with the polyimide processing solution is transported into a chamber of a heat treatment apparatus for heat treatment. The substrate is then placed on a hot plate heated to a predetermined temperature within the chamber. After the transportation of the substrate into the chamber, an inert gas such as a nitrogen gas is introduced into the chamber to provide a low oxygen concentration atmosphere within the chamber. When the substrate is heated to not less than the critical temperature for reaction (referred to hereinafter as a “critical reaction temperature”) of the polyimide in the low oxygen concentration atmosphere, a chemical reaction occurs in the polyimide on the substrate to form an interlayer insulation film having a relatively low dielectric constant and a high degree of flatness.

However, the formation of the interlayer insulation film by the above-mentioned background art method presents problems to be described below. To reduce the dielectric constant of the interlayer insulation film, it is necessary to heat the substrate coated with the processing solution of polyimides, SOD or the like in a low oxygen concentration atmosphere. In the background art method, the substrate is heated up to a predetermined temperature immediately after the substrate is transported into the chamber in which the ambient atmosphere is left. This increases the dielectric constant of the interlayer insulation film.

More specifically, as the substrate coated with the processing solution of polyimides, SOD or the like is transported into the chamber, outside air flows into the chamber to cause the oxygen concentration in the chamber to approach the oxygen concentration in the ambient atmosphere. For this reason, the inert gas is introduced into the chamber to provide the low oxygen concentration atmosphere within the chamber. However, during the time between the instant immediately after the transportation of the substrate into the chamber and the instant at which the low oxygen concentration atmosphere is provided, the substrate is heated to not less than the critical reaction temperature at which a chemical reaction occurs in the processing solution coating the substrate. As a result, the chemical reaction occurs in an atmosphere of a relatively high oxygen concentration to cause oxygen molecules to be introduced into the interlayer insulation film, thereby forming the interlayer insulation film having a relatively high dielectric constant.

To prevent the above phenomenon, the heating of the substrate up to not less than the critical reaction temperature is required to await a predetermined oxygen concentration or lower reached within the chamber into which the nitrogen gas is introduced after the transportation of the substrate into the chamber. However, it takes much time for the oxygen concentration within the chamber to reach the predetermined oxygen concentration or lower. This presents another problem in low processing efficiency.

Additionally, if the substrate heated to an elevated temperature is transported out of the chamber immediately after the completion of the heating process, oxygen molecules are introduced into the interlayer insulation film, thereby increasing the dielectric constant of the interlayer insulation film formed by the firing process. It is therefore necessary to transport the substrate out of the chamber after the substrate is cooled down to a temperature lower than the critical reaction temperature in the low oxygen concentration atmosphere within the chamber. However, it also takes much time to cool down the high-temperature substrate within the chamber, and the problem of low processing efficiency as in the heating process is also encountered.

To solve these problems, one of the present inventors proposes a heat treatment apparatus disclosed in U.S. Pat. No. 6,403,924. This apparatus, in which a substrate is heat-treated in a low oxygen concentration atmosphere, is capable of forming an interlayer insulation film having a low dielectric constant. Additionally, this apparatus is capable of achieving rapid heating and cooling to provide high processing efficiency.

In the apparatus disclosed in U.S. Pat. No. 6,403,924, a nitrogen gas flow is produced from the interior of a chamber toward an opening to prevent an ambient atmosphere from flowing into the chamber. However, the disclosed apparatus minimizes the flow rate of the gas flow within the chamber to hold a uniform temperature distribution of a heater during a substrate heating process. The disclosed apparatus, on the other hand, is adapted so that a substrate and an arm for holding the substrate are as close to each other as possible for the purpose of high cooling efficiency during the cooling of the substrate subjected to heating and held by the arm. It is hence difficult to completely remove an ambient atmosphere between the substrate and the arm by the use of the gas flow at the minimized flow rate, which results in part of the ambient atmosphere carried into the chamber during the transportation of the substrate.

Further, a substrate processing apparatus adaptable to recent substrates having a diameter of 300 mm includes a large arm. The use of only the gas flow in the chamber might cause the ambient atmosphere to be dragged into the chamber.

As described above, the increase in oxygen concentration due to the flow of the ambient atmosphere into the chamber at the time of the transportation of the substrate creates a problem such that it is difficult to completely solve the above-mentioned conventional problems.

### SUMMARY OF THE INVENTION

The present invention is intended for a heat treatment apparatus for performing heat treatment upon a substrate coated with a processing solution to form a predetermined film on the substrate.

According to the present invention, the heat treatment apparatus comprises: a processing chamber for performing the heat treatment upon a substrate; a nitrogen gas supply part for supplying nitrogen gas into the processing chamber to maintain a low oxygen concentration atmosphere within the processing chamber; a heating part in the processing chamber for placing thereon the substrate loaded into the processing chamber to heat the substrate; a loading/unloading part movable into and out of the processing chamber for loading and unloading the substrate into and out of the processing chamber; a cooling part in the loading/unloading part for cooling the substrate held by the loading/unloading part; and an ejection part for ejecting nitrogen gas toward a space between the substrate held by the loading/unloading part and the loading/unloading part.

Supplying the nitrogen gas to the space between the substrate and the loading/unloading part causes the ambient atmosphere in the space to be replaced with the nitrogen gas. The loading/unloading part is prevented from bringing the ambient atmosphere into the processing chamber. As a result, the increase in oxygen concentration within the processing chamber is reliably inhibited.

Preferably, the ejection part further provides a nitrogen gas atmosphere around the loading/unloading part.

The entire loading/unloading part is surrounded by the nitrogen gas atmosphere, and is more reliably prevented from bringing the ambient atmosphere into the processing chamber. As a result, the increase in oxygen concentration within the processing chamber is more reliably inhibited. Additionally, the amount of nitrogen gas supplied from the nitrogen gas supply part is reduced.

The present invention is also intended for a substrate processing apparatus for coating a substrate with a processing solution and performing heat treatment upon the substrate to form a predetermined film on the substrate.

It is therefore an object of the present invention to provide a heat treatment apparatus capable of reliably inhibiting the increase in oxygen concentration within a processing chamber, and a substrate processing apparatus including the heat treatment apparatus.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of an example of the overall construction of a substrate processing apparatus;

FIG. 2 shows an example of process steps in the substrate processing apparatus of FIG. 1;

FIG. 3 is a plan view of a heat treatment apparatus incorporated in the substrate processing apparatus of FIG. 1;

FIG. 4 is a side sectional view of the heat treatment apparatus incorporated in the substrate processing apparatus of FIG. 1;

FIG. 5 is a top plan sectional view of a heating unit in the heat treatment apparatus incorporated in the substrate processing apparatus of FIG. 1;

FIGS. 6 through 10 show respective steps of a procedure in the heat treatment apparatus;

FIG. 11 shows nitrogen gas being ejected from a transport arm;

FIG. 12 shows a correlation between the heating temperature of a low-dielectric-constant material and the degree of reaction thereof;

FIGS. 13A and 13B show a transport arm according to a second preferred embodiment of the present invention;

FIG. 14 is a side sectional view of the heat treatment apparatus according to a third preferred embodiment of the present invention; and

FIG. 15 is a side sectional view of the heat treatment apparatus according to a fourth preferred embodiment of the present invention.

### DESCRIPTION OF THE PREFERRED EMBODIMENTS

### 1. First Preferred Embodiment

Preferred embodiments according to the present invention will now be described in detail with reference to the drawings.

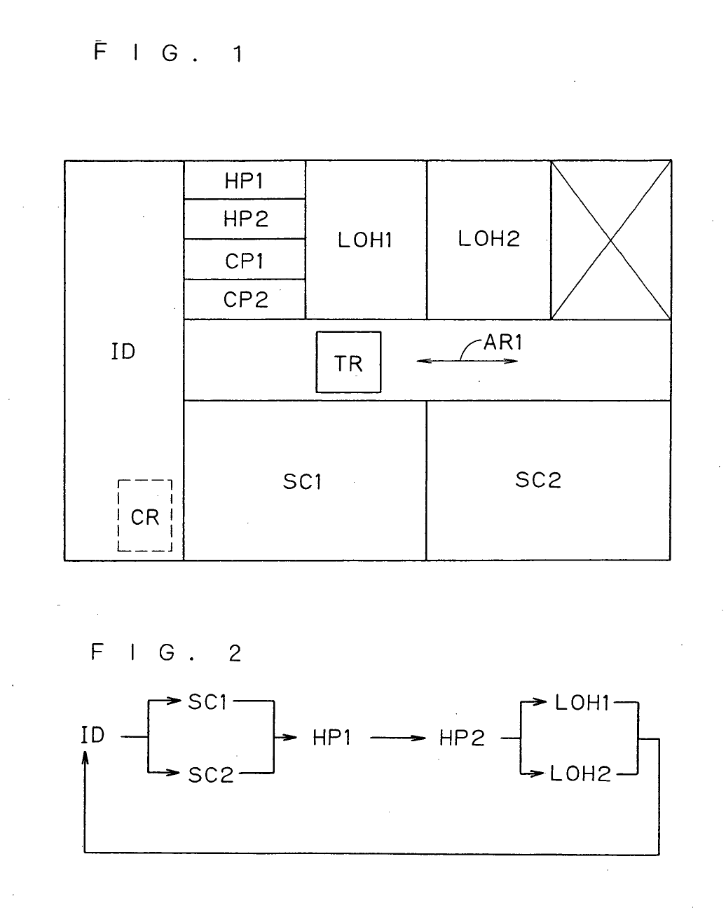

Description will be given first on the overall construction of a substrate processing apparatus including a heat treatment apparatus incorporated therein according to the present invention. FIG. 1 is a plan view of an example of the overall construction of the substrate processing apparatus. The substrate processing apparatus of FIG. 1 includes an indexer ID for transferring a substrate W to a transport robot TR; spinning-type coating apparatuses (spin coaters) SC1 and SC2 for coating the substrate W with a low-dielectric-constant material such as SOD and polyimides; heat treatment apparatuses LOH1 and LOH2 according to the present invention; hot plate units HP1 and HP2 for heating the substrate W; cool plate units CP1 and CP2 for cooling the substrate W; and the transport robot TR for transporting the substrate W among the above-mentioned components of the substrate processing apparatus.

The indexer ID is capable of placing thereon a plurality of cassettes or carriers each of which can accommodate a plurality of substrates W, and includes a transfer mechanism (not shown) for transferring a substrate W between a cassette and the transport robot TR. The indexer ID has the functions of transferring an unprocessed substrate W stored in a cassette to the transport robot TR and receiving a processed substrate W from the transport robot TR to store the processed substrate W in a cassette.

The spin coaters SC1 and SC2 discharge a processing solution of a low-dielectric-constant material such as SOD and polyimides onto a substrate W while spinning the substrate W held in a substantially horizontal position to coat the substrate W with the low-dielectric-constant material.

The heat treatment apparatuses LOH1 and LOH2 have the function of performing heat treatment in a low oxygen concentration atmosphere upon the substrate W coated with the processing solution of the low-dielectric-constant material such as SOD and polyimides, thereby to form an interlayer insulation film on the substrate W. The heat treatment apparatuses LOH1 and LOH2 will be described in detail later.

The hot plate units HP1 and HP2 include a heating mechanism and have the function of heating a substrate W transported therein up to a predetermined temperature. The cool plate units CP1 and CP2 include a cooling mechanism and have the functions of cooling a substrate W transported therein down to a predetermined temperature and maintaining the substrate W at the predetermined temperature. The hot plate units HP1, HP2 and the cool plate units CP1, CP2 are vertically stacked in the order named from top to bottom, but are shown in FIG. 1 as arranged in a horizontal plane for purposes of illustration.

The transport robot TR is horizontally movable as indicated by an arrow AR1 along a transport road disposed between a processing unit array including the spin coaters SC1 and SC2 and a processing unit array including the heat treatment apparatuses LOH1, LOH2, the hot plate units HP1, HP2 and the cool plate units CP1, CP2. The transport robot TR is rotatable and vertically movable by a drive mechanism not shown. This allows the transport robot TR to transport a substrate W among the indexer ID and the above-mentioned processing units SC1, SC2, LOH1, LOH2, HP1, HP2, CP1, CP2.

The substrate processing apparatus contains a controller CR constructed by the use of a computer. The controller CR is electrically connected to the above-mentioned processing units and controls the operations of the processing units and the substrate transportation of the transport robot TR in accordance with a predetermined processing program.

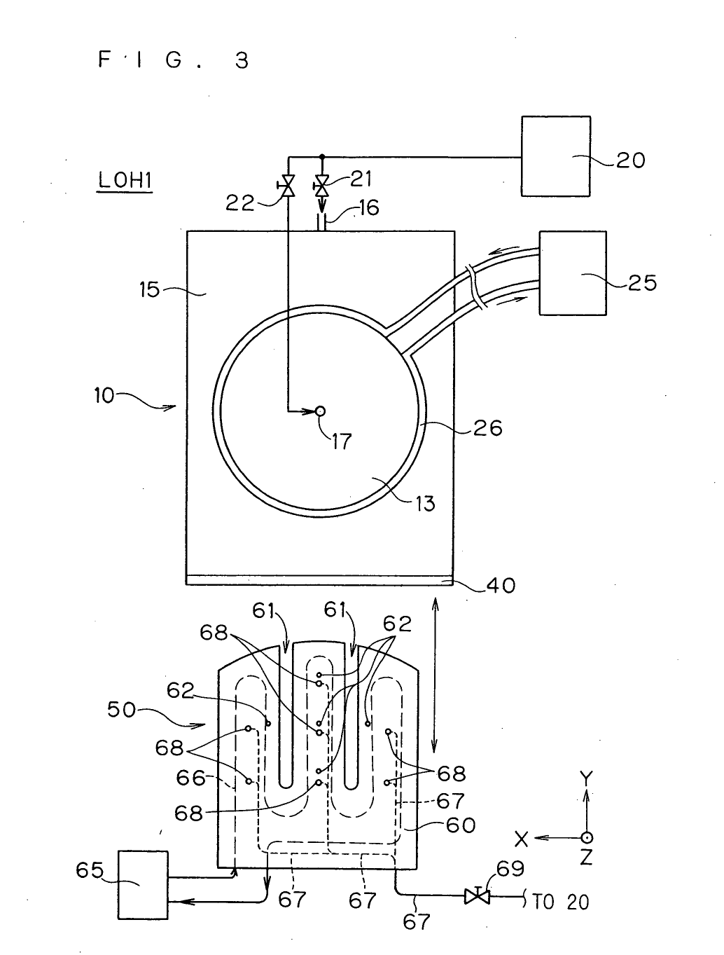

Brief description will be given on the overall procedure in the substrate processing apparatus having the above construction. FIG. 2 shows an example of process steps in the substrate processing apparatus of FIG. 1. The processing units to which a substrate W is transported are shown in FIG. 2 in the order of the transportation. Every transportation of a substrate W among the processing units is effected by the transport robot TR in accordance with an instruction from the controller CR. The processing in the processing units is carried out also in accordance with an instruction from the controller CR.

When a cassette having unprocessed substrates stored therein is placed on the indexer ID, an unprocessed substrate W is transferred from the cassette to the transport robot TR. The transport robot TR transports the received unprocessed substrate W into either of the spin coaters SC1 and SC2. The spin coater SC1 or SC2 which receives the unprocessed substrate W coats the substrate W with a processing solution of SOD while spinning the substrate W. The processing solution for coating is not limited to SOD but may be of other low-dielectric-constant materials such as polyimides. Whether to transport the substrate W into the spin coater SC1 or the spin coater SC2 may be determined by the vacancy thereof at that point of time (which is so-called parallel processing). This is because the coating process requires longer time than other processes.

After the coating process is completed, the transport robot TR transports the substrate W from the spin coater SC1 or SC2 into the hot plate unit HP1. The hot plate unit HP1 heats the substrate W coated with the processing solution of SOD up to a predetermined temperature. This heat treatment is a pre-heating process for the process of forming an interlayer insulation film by firing in the heat treatment apparatuses LOH1 and LOH2. Heating temperature in the hot plate unit HP1 (lower than the critical reaction temperature of the low-dielectric-constant material) is much lower than the heat treatment temperature in the heat treatment apparatuses LOH1 and LOH2.

Thereafter, the transport robot TR transports the substrate W from the hot plate unit HP1 into the hot plate unit HP2. The hot plate unit HP2 also heats the substrate W up to a predetermined temperature. This heat treatment is also a pre-heating process for the process of forming the interlayer insulation film by firing in the heat treatment apparatuses LOH1 and LOH2. Heating temperature in the hot plate unit HP2 is intermediate between the heat treatment temperature in the heat treatment apparatuses LOH1 and LOH2 and the heat treatment temperature in the hot plate unit HP1, but is also lower than the critical reaction temperature of the low-dielectric-constant material.

After the heating process in the hot plate unit HP2 is completed, the transport robot TR transports the substrate W from the hot plate unit HP2 into either of the heat treatment apparatuses LOH1 and LOH2. The heat treatment apparatus LOH1 or LOH2 performs the process of firing the substrate W in a low oxygen concentration atmosphere to form an interlayer insulation film on the substrate W. The heat treatment in the heat treatment apparatus LOH1 or LOH2, which is to be described in detail later, includes heating the substrate W at a temperature not less than the critical reaction temperature of the low-dielectric-constant material to form the interlayer insulation film by firing. As illustrated in FIG. 2, the heat treatment in the heat treatment apparatus LOH1 or LOH2 is parallel processing, and the substrate W may be transported into either of the heat treatment apparatuses LOH1 and LOH2.

After the firing process of the interlayer insulation film on the substrate W in the heat treatment apparatus LOH1 or LOH2 is completed, the transport robot TR transports the substrate W from the heat treatment apparatus LOH1 or LOH2, and returns the processed substrate W to the indexer ID. The indexer ID stores the processed substrate W into a cassette. Then, the cassette in which a predetermined number of processed substrates are stored is carried out of the substrate processing apparatus. The substrate W subjected to the heat treatment in the heat treatment apparatus LOH1 or LOH2 may be transported once into the cool plate unit CP1 or CP2 before being returned to the indexer ID. Thus, a sequence of processes for the formation of the interlayer insulation film on the substrate W is completed.

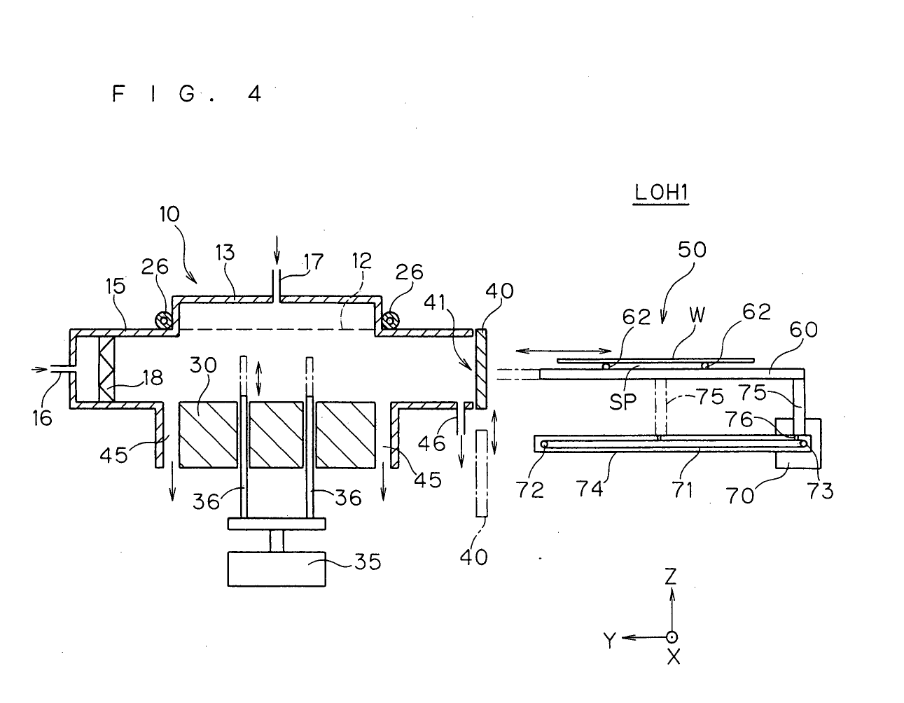

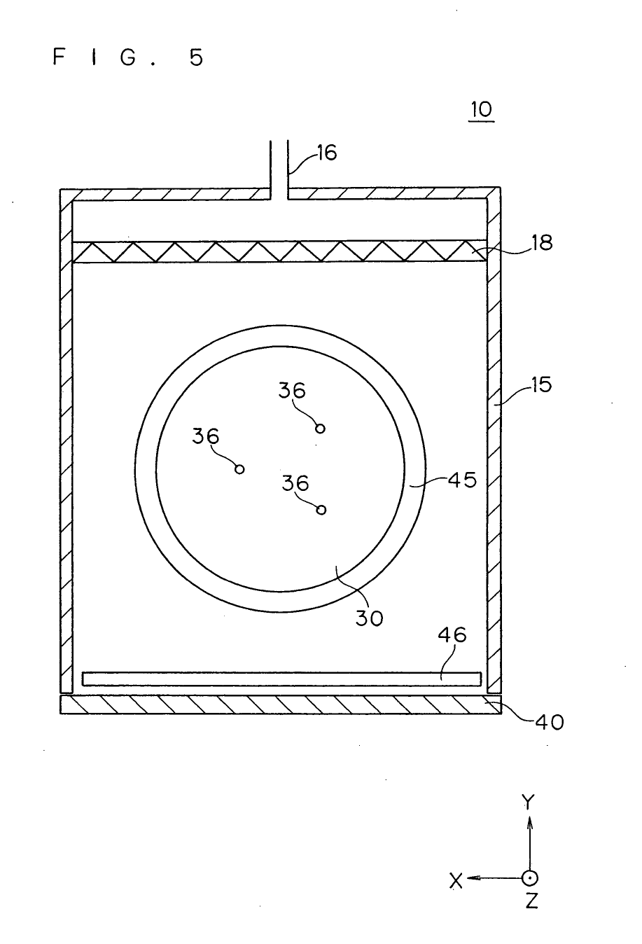

Next, the construction of the heat treatment apparatuses LOH1 and LOH2 incorporated in the substrate processing apparatus will be described. Although description will be given hereinafter on only the heat treatment apparatus LOH1, the heat treatment apparatus LOH2 is completely identical in construction with the heat treatment apparatus LOH1. FIG. 3 is a plan view of the heat treatment apparatus LOH1. FIG. 4 is a side sectional view of the heat treatment apparatus LOH1. FIG. 5 is a top plan sectional view of a heating unit 10 in the heat treatment apparatus LOH1. An XYZ rectangular coordinate system in which the horizontal plane is defined as an XY plane and the vertical direction as a Z direction is additionally shown in FIGS. 3 through 5 for purposes of clarifying the directional relationship therebetween.

The heat treatment apparatus LOH 1 principally includes the heating unit 10 and a load/unload unit 50. The heating unit 10 has the function of performing a heating process in a low oxygen concentration atmosphere. The load/unload unit 50 has the functions of transporting a substrate W into or out of the heating unit 10 and cooling the substrate W.

The heating unit 10 includes a chamber 15 having a heater 30 disposed therein. The chamber 15 is an enclosure of a substantially rectangular parallelepiped configuration, and has a ceiling portion 13 of a cylindrical configuration. The chamber 15 serves as a processing chamber for performing heat treatment for the formation of the interlayer insulation film on the substrate W loaded therein. A low oxygen concentration atmosphere maintaining mechanism to be described later always maintains the low oxygen concentration atmosphere within the chamber 15.

The heater 30 is a disc-shaped member having therein a heat source by means of resistance heating and the like, and maintains a predetermined temperature previously set. Three support pins 36 are provided extending through the heater 30 in the vertical direction (Z direction). The three support pins 36 are capable of abutting against the back surface of a substrate W to support the substrate W, and is vertically movable by an elevating unit 35. The elevating unit 35 may comprise, for example, an air cylinder. With the substrate W supported by the three support pins 36, the elevating unit 35 vertically moves the support pins 36 to vertically move the substrate W supported by the support pins 36 between a heating position directly above the heater 30 and a substrate transfer position over the heating position. When the substrate W is supported at the heating position by the support pins 36, the substrate W is heated to a predetermined temperature by the heater 30.

The chamber 15 includes an opening 41 for loading/unloading the substrate W into/out of the chamber 15 therethrough. The opening 41 is positioned laterally outwardly of a first end of the substrate W placed on the heater 30, i.e., the substrate W supported at the heating position by the support pins 36. The chamber 15 further includes a gate valve 40 vertically movable by a drive mechanism not shown. The opening 41 is closed by the upward movement of the gate valve 40 and is opened by the downward movement of the gate valve 40. When the opening 41 is open with the gate valve 40 lowered, the load/unload unit 50 loads/unloads the substrate W into/out of the chamber 15 through the opening 41. When the opening 41 is closed with the gate valve 40 raised, a closed space is defined within the chamber 15.

The above-mentioned low oxygen concentration atmosphere maintaining mechanism principally includes a gas inlet 16 and an exhaust outlet 46. The low oxygen concentration atmosphere maintaining mechanism serves to maintain the low oxygen concentration atmosphere within the chamber 15 when the opening 41 is open with the gate valve 40 lowered.

The gas inlet 16 is positioned laterally outwardly of a second end of the substrate W on the opposite side of the substrate W from the opening 41, with the substrate W placed on the heater 30. The gas inlet 16 is connected through a valve 21 to a nitrogen gas supply unit 20. With the valve 21 in an open position, nitrogen gas supplied from the nitrogen gas supply unit 20 flows laterally into the chamber 15 through the gas inlet 16 on the side of the second end of the substrate W. A diffusion filter 18 is provided within the chamber 15 in proximity to the gas inlet 16. The nitrogen gas fed into the chamber 15 through the gas inlet 16 is diffused by the diffusion filter 18 to produce a uniform laminar flow in the horizontal direction (Y direction) within the chamber 15, i.e., in parallel to a main surface of the substrate W placed on the heater 30.

When the opening 41 is open, the produced laminar flow exits from the chamber 15 through the opening 41. The uniform laminar flow of nitrogen gas produced in parallel to the main surface of the substrate W within the chamber 15 and exiting from the chamber 15 through the opening 41 prevents outside air from entering the chamber 15 through the opening 41 to avoid a flow of oxygen into the chamber 15, consequently maintaining the low oxygen concentration atmosphere within the chamber 15.

The exhaust outlet 46 is provided in linear form immediately before the gate valve 40 within the chamber 15, i.e., under the opening 41. The exhaust outlet 46 is connected to an exhaust line provided outside the figures through a valve not shown. The valve may be opened to exhaust gases from the chamber 15 through the exhaust outlet 46. When the opening 41 is closed with the gate valve 40 raised, the laminar flow produced within the chamber 15 exits from the chamber 15 through the exhaust outlet 46. When the opening 41 is open with the gate valve 40 lowered, a slight amount of outside air flowing through the opening 41 is exhausted through the exhaust outlet 46. This prevents outside air from entering the chamber 15 to maintain the low oxygen concentration atmosphere within the chamber 15.

The chamber 15 further includes a gas inlet 17 and an exhaust outlet 45. The gas inlet 17 is provided in a central part of the ceiling portion 13 of the chamber 15. The gas inlet 17 is connected through a valve 22 to the above-mentioned nitrogen gas supply unit 20. With the valve 22 in an open position, nitrogen gas supplied from the nitrogen gas supply unit 20 flows downwardly into the chamber 15 through the gas inlet 17.

The exhaust outlet 45 is provided in annular form around the heater 30 within the chamber 15. The exhaust outlet 45 is connected to an exhaust line provided outside the figures through a valve not shown. The valve may be opened to exhaust gases from the chamber 15 through the exhaust outlet 45.

The gas inlet 17 and the exhaust outlet 45 differ from the gas inlet 16 and the exhaust outlet 46 in operating principally during the heating of the substrate W in the chamber 15. Specifically, during the heating of the substrate W, the nitrogen gas supplied into the chamber 15 through the gas inlet 17 is exhausted through the exhaust outlet 45. This removes impurities sublimed from the substrate W by heating, and also prevents convection of gases from occurring within the chamber 15.

The chamber 15 further includes a top 12 inside the ceiling portion 13. The top 12 is a disc-shaped member having a multiplicity of ventilating openings for passage of the nitrogen gas flowing into the chamber 15 through the gas inlet 17. An annular cooling pipe 26 surrounds an outer wall of the ceiling portion 13. The cooling pipe 26 is connected to a coolant supply unit 25. A coolant supplied from the coolant supply unit 25 is adapted to be fed through the inside of the cooling pipe 26 back to the coolant supply unit 25. The coolant supplied from the coolant supply unit 25 to the cooling pipe 26 cools down the ceiling portion 13 and the top 12 provided inside the ceiling portion 13 through the cooling pipe 26. The substrate W is cooled down by positioning the substrate W in proximity to the cooled top 12.

The load/unload unit 50 principally includes a transport arm 60 and a motor 70 for driving the transport arm 60. The transport arm 60 includes a plurality of protrusions 62 and two indentations 61. The plurality of protrusions 62 abut against the back surface of the substrate W to support the substrate W, whereby the transport arm 60 can hold the substrate W thereon. The two indentations 61 are adapted to receive the support pins 36 of the heating unit 10. This prevents the movement of the transport arm 60 into and out of the chamber 15 and the vertical movement of the support pins 36 from interfering with each other. The transport arm 60 can move into the chamber 15 with the support pins 36 in its raised position, and the support pins 36 can move upwardly with the transport arm 60 moved in the chamber 15.

As illustrated in FIG. 3, a plurality of (in this preferred embodiment, seven) circular gas ejection ports 68 for ejecting nitrogen gas are distributed throughout a region of an upper surface of the transport arm 60 of the load/unload unit 50, the region being opposed to the back surface of the substrate W held by the transport arm 60. Specifically, the seven gas ejection ports 68 are arranged symmetrically with respect to a centerline extending in a direction in which the transport arm 60 moves into or out of the chamber 15 (in the Y direction) so that areas of the substrate W covered with the nitrogen gas ejected from the respective gas ejection ports 68 are approximately equal to each other. The gas ejection ports 68 are slightly different in diameter from each other so that the areas of the substrate W covered with the nitrogen gas ejected from the respective gas ejection ports 68 are approximately equal to each other. Such slightly different diameters of the gas ejection ports 68 are provided because some of the nitrogen gas leaks from the indentations 61 formed in the transport arm 60 so that simply uniformly distributing the gas ejection ports 68 does not make the areas of the substrate W covered with the nitrogen gas ejected from the respective gas ejection ports 68 approximately equal to each other.

As illustrated also in FIG. 3, gas supply piping 67 is disposed inside the transport arm 60. Branches of the gas supply piping 67 in the transport arm 60 are connected to the gas ejection ports 68, respectively. The gas supply piping 67 is connected to the nitrogen gas supply unit 20 through a valve 69 electrically connected to the controller CR (see FIG. 1) outside the transport arm 60.

With such an arrangement, when the valve 69 is opened with the substrate W held on the transport arm 60, the nitrogen gas is supplied from the nitrogen gas supply unit 20 to the transport arm 60. This achieves the substantially uniform ejection of the nitrogen gas throughout a space SP defined between the back surface of the substrate W held by the transport arm 60 and the transport arm 60, as shown in FIG. 4.

As illustrated in FIG. 3, cooling piping 66 is disposed inside the transport arm 60. The cooling piping 66 is connected to a coolant supply unit 65. A coolant supplied from the coolant supply unit 65 is fed through the inside of the cooling piping 66 back to the coolant supply unit 65. In other words, the coolant supply unit 65 circulates the coolant through the cooling piping 66. The coolant passing through the cooling piping 66 substantially uniformly cools down at least a region of the transport arm 60 which is opposed to the substrate W held by the transport arm 60. This cools down the substrate W held by the transport arm 60.

The transport arm 60 is movable in the Y direction by a drive mechanism including the motor 70, a driving pulley 73, a driven pulley 72 and a belt 71. The driving pulley 73 is fixed to the motor shaft of the motor 70. The driven pulley 72 is free to rotate. The belt 71 is wound around the driving pulley 73 and the driven pulley 72. Thus, as the motor 70 is driven in the normal or reverse direction, the driving pulley 73 accordingly rotates to cause the belt 71 to run around the driving pulley 73 and the driven pulley 72.

An arm support 75 extends vertically from beneath the transport arm 60. The arm support 75 is free to slide relative to a guide member 74. The arm support 75 and the belt 71 are coupled to each other through a coupling member 76. Thus, as the motor 70 is driven to cause the belt 71 to run around, the arm support 75 slides in the Y direction to accordingly move the transport arm 60 into and out of the chamber 15. Because of such movement of the transport arm 60 into and out of the chamber 15, the transport arm 60 can transport the substrate W into and out of the chamber 15. For example, flexible tubes or the like may be used for the piping for feeding the coolant and the nitrogen gas to the transport arm 60 so that the transport arm 60 can move into and out of the chamber 15.

Although the construction of the heat treatment apparatus LOH1 is described above, the mechanism for driving the transport arm 60 in the Y direction is not limited to the above-mentioned belt-driven mechanism, but may be a mechanism capable of driving the transport arm 60 linearly in the Y direction, for example, a feed screw mechanism having a combination of a ball screw and an internally threaded screw. The means for cooling the substrate W held by the transport arm 60 is not limited to the coolant supply but may be other cooling mechanisms, for example, a Peltier element.

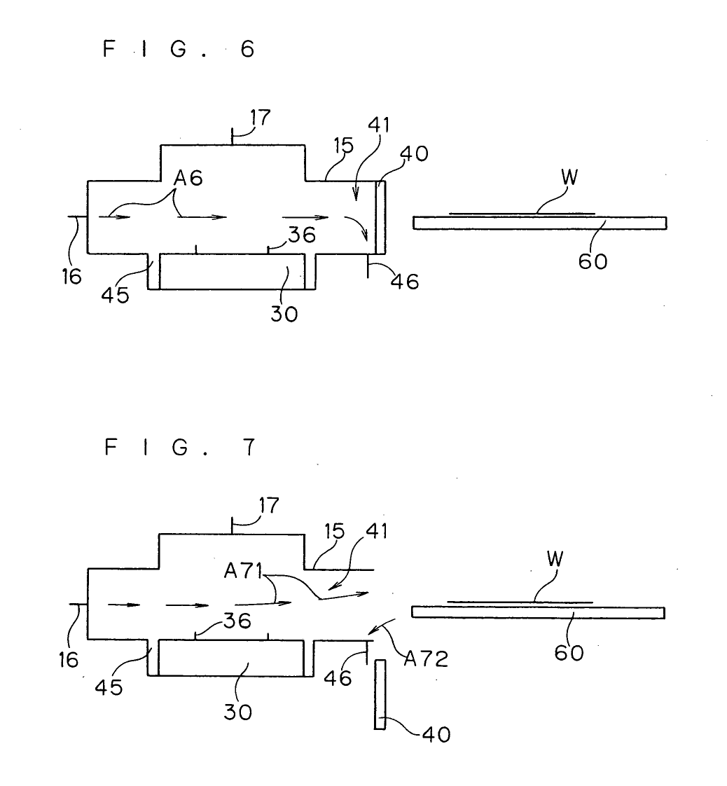

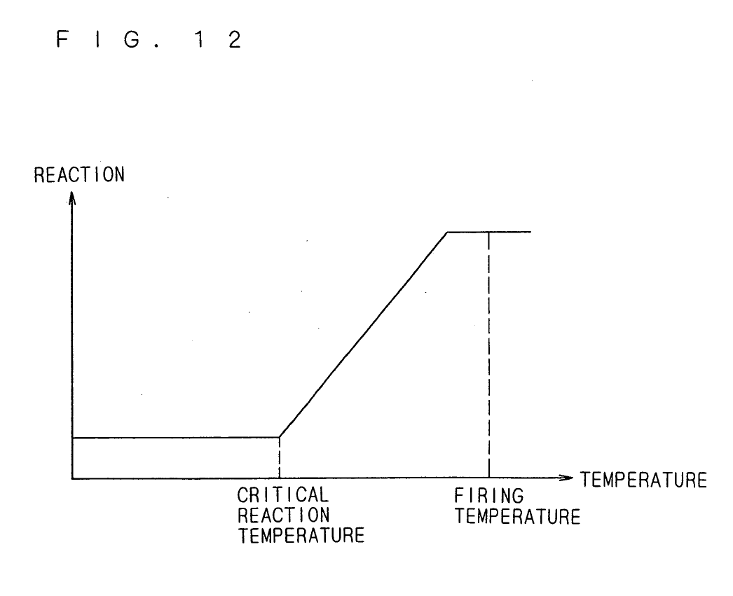

Next, a procedure in the heat treatment apparatuses LOH1 and LOH2 will be described with reference to FIGS. 6 through 11. FIGS. 6 through 10 show respective steps of the procedure in the heat treatment apparatus LOH1. FIG. 11 shows nitrogen gas being ejected from the transport arm 60. Although description will be given hereinafter on only the heat treatment apparatus LOH1, the heat treatment apparatuses LOH1 and LOH2 perform parallel processing and the heat treatment apparatus LOH2 is completely identical in procedure with the heat treatment apparatus LOH1. Every processing in the heat treatment apparatus LOH1 is performed in accordance with an instruction from the controller CR.

As stated above, a substrate W pre-heated in the hot plate unit HP2 is transported by the transport robot TR into the heat treatment apparatus LOH1. More specifically, the transport robot TR transfers the pre-heated substrate W to the transport arm 60. FIG. 6 shows the heat treatment apparatus LOH1 with the substrate W transferred to the transport arm 60. When the substrate W is transferred to the transport arm 60, the valve 21 of the gas inlet 16 and the valve of the exhaust outlet 46 are opened. Nitrogen gas flows through the gas inlet 16 into the chamber 15. The nitrogen gas is diffused by the diffusion filter 18 to produce a uniform laminar flow in the horizontal direction (Y direction) within the chamber 15, as indicated by the arrows A6 of FIG. 6. At this time, the gate valve 40 is in its raised position to close the opening 41, and the laminar flow of nitrogen gas produced within the chamber 15 exits from the chamber 15 through the exhaust outlet 46. In this step, the supply of nitrogen gas through the gas inlet 17 and the exhaust through the exhaust outlet 45 are not carried out.

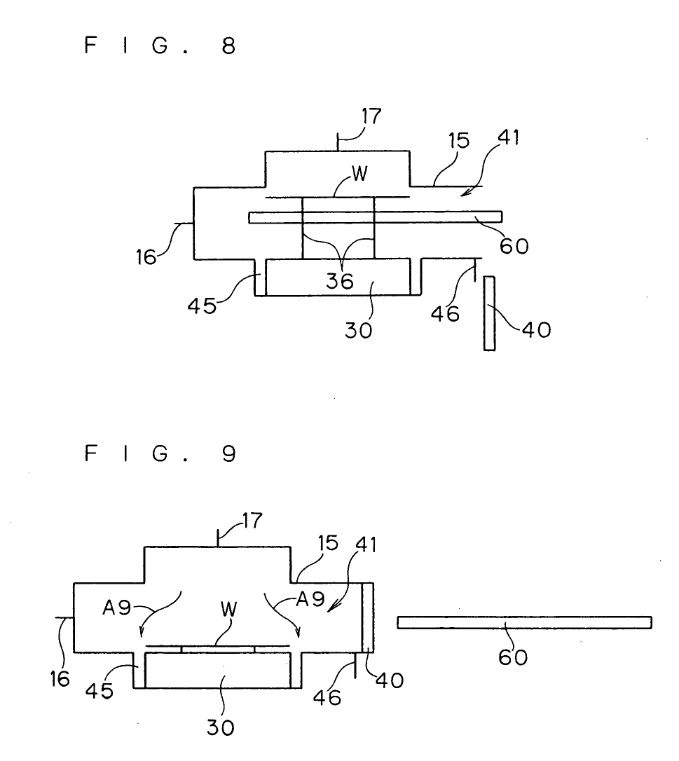

Next, the gate valve 40 is lowered to open the opening 41. FIG. 7 shows the heat treatment apparatus LOH1 with the opening 41 open. The opening 41 in its open position permits the laminar flow of nitrogen gas produced within the chamber 15 to exit from the chamber 15 through the opening 41, as indicated by the arrows A71 of FIG. 7. As mentioned above, the uniform laminar flow of nitrogen gas exiting from the chamber 15 through the opening 41 prevents outside air from entering the chamber 15 through the opening 41 to avoid a flow of oxygen into the chamber 15, consequently maintaining the low oxygen concentration atmosphere within the chamber 15.

The laminar flow of nitrogen gas produced within the chamber 15 exits from the chamber 15 through the opening 41 while moving slightly upwardly as indicated by the arrows A71 of FIG. 7 because the laminar flow of nitrogen gas is warmed up by the heater 30. As a result, outside air is dragged into a lower part of the opening 41, and a small amount of ambient atmosphere flows into the chamber 15 through the opening 41. However, the outside air dragged into the opening 41 is exhausted through the exhaust outlet 46 under the opening 41 as indicated by the arrow A72 of FIG. 7. This prevents the ambient atmosphere from entering the chamber 15 to maintain the low oxygen concentration atmosphere within the chamber 15. Thus, the exhaust outlet 46 has the two functions of exhausting the laminar flow of nitrogen gas when the opening 41 is closed and preventing outside air from entering the chamber 15 when the opening 41 is open.

A predetermined period of time (for example, several seconds) before the start of the operation of the transport arm 60 to be described below, the supply of nitrogen gas from the nitrogen gas supply unit 20 to the transport arm 60 is commenced by opening the valve 69. This commences the ejection of the nitrogen gas from the gas ejection ports 68 to the entire space SP between the back surface of the substrate W held by the transport arm 60 and the transport arm 60 as indicated by the arrows AR2 of FIG. 11. The flow rate of the nitrogen gas ejected at this time is not less than about several liters per minute (in this preferred embodiment, about 3 l/min). This expels the ambient atmosphere between the substrate W and the transport arm 60 from the space SP to replace the ambient atmosphere with a nitrogen gas atmosphere in the space SP, thereby preventing the transport arm 60 from bringing the ambient atmosphere into the chamber 15 when the transport arm 60 enters the chamber 15.

Next, the transport arm 60 which holds the substrate W moves forward into the chamber 15. The transport arm 60 stops at a predetermined position (at which the substrate W is directly above the heater 30) within the chamber 15. Then, the support pins 36 move upwardly to abut against the back surface of the substrate W, and lift the substrate W to separate the substrate W from the transport arm 60. In other words, the substrate W is transferred from the transport arm 60 to the support pins 36. FIG. 8 shows the heat treatment apparatus LOH1 with the substrate W transferred from the transport arm 60 to the support pins 36.

In this step, the laminar flow is produced within the chamber 15 by supplying the nitrogen gas through the gas inlet 16 and exits from the chamber 15 through the opening 41, and outside air dragged into the opening 41 is exhausted through the exhaust outlet 46, in the above-mentioned manner. Therefore, the low oxygen concentration atmosphere is maintained within the chamber 15. Additionally, the nitrogen gas continues to be ejected from the gas ejection ports 68 of the transport arm 60.

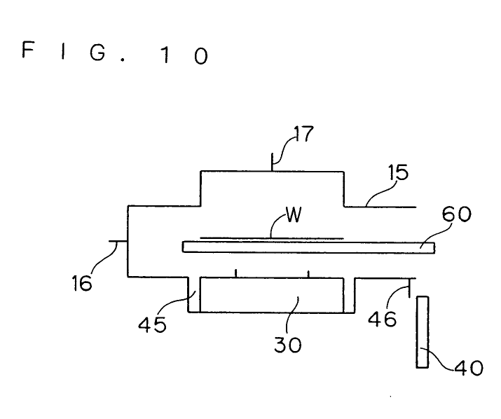

Next, the transport arm 60 from which the substrate W is transferred to the support pins 36 moves backward to exit from the chamber 15. Then, the gate valve 40 is raised to close the opening 41. Thereafter, the support pins 36 supporting the substrate W move downwardly to move the substrate W downwardly to the heating position directly above the heater 30. Since the temperature of the heater 30 has already been raised to a predetermined temperature, the heating of the substrate W starts as soon as the substrate W is moved downwardly to the heating position directly above the heater 30. FIG. 9 shows the heat treatment apparatus LOH1 during the heating of the substrate W.

In this step, the supply of the nitrogen gas through the gas inlet 16 and the exhaust through the exhaust outlet 46 are stopped, and the valve 22 of the gas inlet 17 and the valve of the exhaust outlet 45 are opened. As indicated by the arrows A9 of FIG. 9, the nitrogen gas supplied through the gas inlet 17 passes through the top 12 to produce a downflow, and is then exhausted through the exhaust outlet 45. This removes impurities sublimed from the substrate W by heating, and also suppresses the convection of gases occurring within the chamber 15 to prevent impurities from being deposited on the substrate W. During the heating of the substrate W, no outside air enters the chamber 15 through the opening 41 since the gate valve 40 is in its raised position to close the opening 41. Therefore, the low oxygen concentration atmosphere is maintained within the chamber 15. The supply of the nitrogen gas through the gas ejection ports 68 of the transport arm 60 is stopped by closing the valve 69 when the transport arm 60 exits from the chamber 15.

FIG. 12 shows a correlation between the heating temperature of the low-dielectric-constant material and the degree of reaction thereof. The heating temperatures in the respective hot plate units HP1 and HP2 are lower than the critical reaction temperature of the low-dielectric-constant material. In such a temperature range, oxygen molecules are not introduced into the low-dielectric-constant material. On the other hand, the heating temperature of the substrate W in the heat treatment apparatus LOH1 is a firing temperature not less than the critical reaction temperature. At this firing temperature, the reaction of the low-dielectric-constant material proceeds sufficiently to consequently form the interlayer insulation film by firing. As above discussed, heating the substrate W up to the firing temperature not less than the critical reaction temperature might cause oxygen molecules to be introduced into the interlayer insulation film. However, the technique of this preferred embodiment can always maintain the low oxygen concentration atmosphere within the chamber 15 to prevent oxygen molecules from being introduced into the interlayer insulation film. This provides the low dielectric constant of the interlayer insulation film to be formed.

Additionally, the low oxygen concentration atmosphere is maintained within the chamber 15 also immediately after the substrate W is transported into the chamber 15 (at the time the substrate W is transferred from the transport arm 60 to the support pins 36). Hence, the substrate W may be immediately moved downwardly to the heating position directly above the heater 30 to start being heated. This requires a short length of time to perform the firing process, thereby increasing the processing efficiency.

When the firing process of the substrate W is completed after an elapse of predetermined time, the support pins 36 move upwardly to move the substrate W upwardly from the heating position directly above the heater 30 to the substrate transfer position. Then, the supply of the nitrogen gas through the gas inlet 17 and the exhaust through the exhaust outlet 45 are stopped, and the valve 21 of the gas inlet 16 and the valve of the exhaust outlet 46 are opened. Thus, in the above-mentioned manner, the nitrogen gas flowing into the chamber 15 through the gas inlet 16 produces a uniform laminar flow within the chamber 15, and the laminar flow exits from the chamber 15 through the exhaust outlet 46.

Thereafter, the gate valve 40 is lowered to open the opening 41. In this step similar to the step shown in FIG. 7, the laminar flow is produced within the chamber 15 by supplying the nitrogen gas into the chamber 15 through the gas inlet 16 and exits from the chamber 15 through the opening 41, and the outside air dragged into the opening 41 is exhausted through the exhaust outlet 46. Therefore, the low oxygen concentration atmosphere is maintained within the chamber 15. Then, the transport arm 60 moves forward into the chamber 15, and stops at a predetermined position within the chamber 15. In this step, the coolant is circulated through the cooling piping 66. Additionally, the nitrogen gas may be ejected from the gas ejection ports 68 of the transport arm 60 in this step.

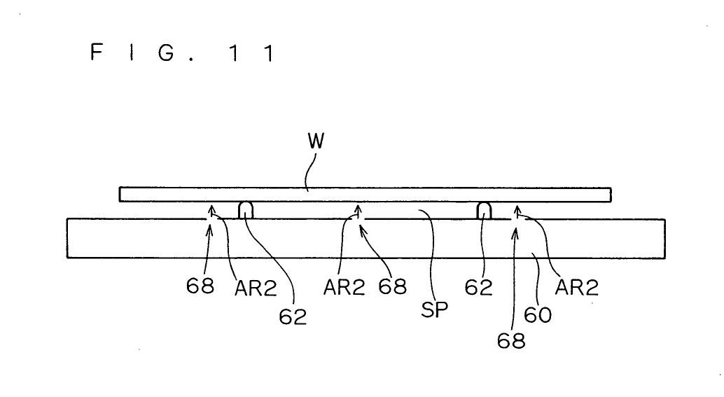

Next, the support pins 36 supporting the substrate W move downwardly, and the substrate W is transferred from the support pins 36 to the transport arm 60. FIG. 10 shows the heat treatment apparatus LOH1 with the substrate W transferred from the support pins 36 to the transport arm 60.

The substrate W held by the transport arm 60 is cooled down within the chamber 15 since the coolant is circulated through the cooling piping 66. Also in this step, the laminar flow is produced within the chamber 15 by supplying the nitrogen gas into the chamber 15 through the gas inlet 16 and exits from the chamber 15 through the opening 41, and the outside air dragged into the opening 41 is exhausted through the exhaust outlet 46. Therefore, the low oxygen concentration atmosphere is maintained within the chamber 15. Since the substrate W after the firing process is cooled down in the low oxygen concentration atmosphere, oxygen molecules are prevented from being introduced into the interlayer insulation film. This provides the low dielectric constant of the interlayer insulation film to be formed.

Additionally, the substrate W is quickly cooled down because the substrate W is cooled by holding the substrate W on the transport arm 60 in which the coolant is circulated.

Next, after an elapse of predetermined time during which the substrate W is cooled down to less than the critical reaction temperature, the transport arm 60 holding the substrate W thereon moves backward out of the chamber 15. That is, after receiving the heated substrate W, the transport arm 60 places the substrate W in a standby condition within the chamber 15 until the temperature of the substrate W becomes lower than the critical reaction temperature, and then exits from the chamber 15. If the substrate W already cooled down to less than the critical reaction temperature is exposed to the ambient atmosphere, oxygen molecules are not introduced into the interlayer insulation film. Then, the transport robot TR receives the substrate W subjected to the heat treatment from the transport arm 60. This completes a sequence of processes in the heat treatment apparatus LOH1.

In this preferred embodiment, as described above, the nitrogen gas is supplied to the space between the substrate W and the transport arm 60 prior to the transportation of the substrate W into the chamber 15. The ambient atmosphere between the substrate W and the transport arm 60 is expelled by the nitrogen gas and is not brought into the chamber 15. This reliably inhibits the increase in oxygen concentration within the chamber 15 to consequently achieve the efficient formation of the interlayer insulation film having a low dielectric constant by firing.

### 2. Second Preferred Embodiment

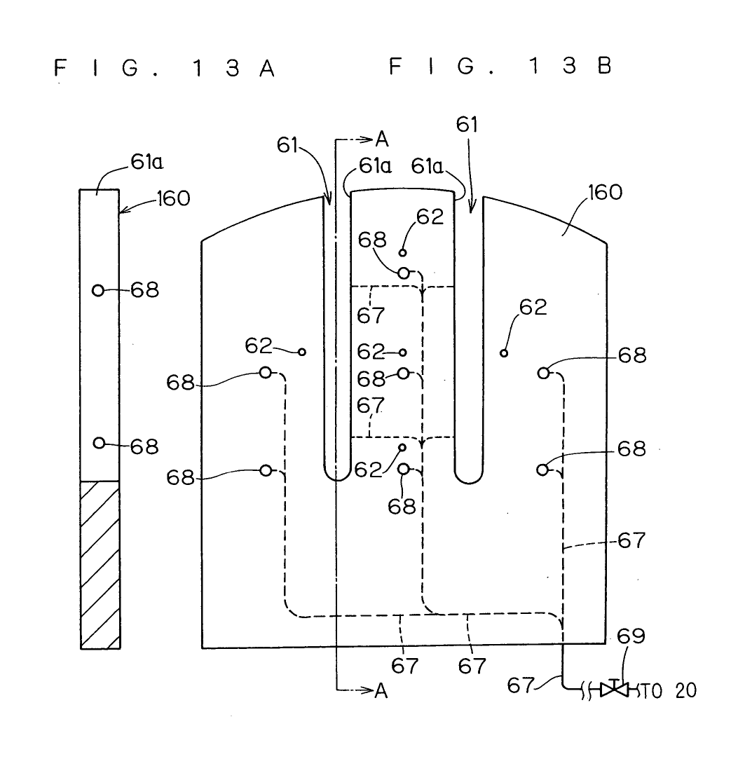

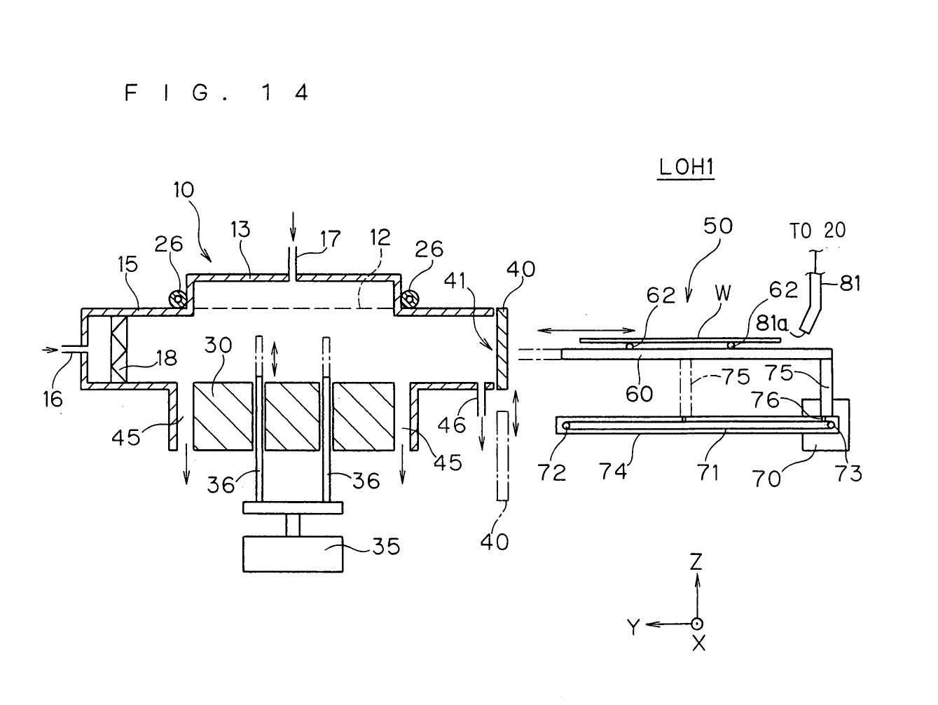

Next, a second preferred embodiment according to the present invention will be described. FIGS. 13A and 13B show a transport arm 160 according to the second preferred embodiment. FIG. 13A is a sectional view taken along the line A-A in FIG. 13B and looking in the direction of the appended arrows, and FIG. 13B is a plan view. Many of the constituents of the units of the substrate processing apparatus of the second preferred embodiment are similar to those of the substrate processing apparatus of the first preferred embodiment. These constituents in the second preferred embodiment are designated by reference numerals and characters identical with those in the first preferred embodiment, and will not be described.

As illustrated in FIGS. 13A and 13B, the transport arm 160 according to the second preferred embodiment includes the plurality of gas ejection ports 68 arranged in the upper surface thereof in a similar pattern to those of the transport arm 60 of the first preferred embodiment for ejecting the nitrogen gas. The transport arm 160 further includes a plurality of, specifically two, additional gas ejection ports 68 in a side surface 61a of a recessed portion, more specifically each of the indentations 61, of the transport arm 60. The gas supply piping 67 leading to the nitrogen gas supply unit 20 is also connected to these additional gas ejection ports 68. Other apparatus structures and substrate processing, particularly the timing of the start and stop of the ejection of the nitrogen gas from the gas ejection ports 68, the flow rate of the ejected nitrogen gas and the like, in the second preferred embodiment are identical with those of the first preferred embodiment.

The recessed portion provided with the gas ejection ports 68 is not limited to the indentations 61. If a second recessed portion is formed in the transport arm, the gas ejection ports 68 may be provided in a wall surface of the second recessed portion.

The ambient atmosphere is prone to stay in such a recessed portion and to be brought into the chamber 15 when the transport arm 160 moves into the chamber 15, thereby causing the increase in oxygen concentration. The second preferred embodiment produces effects similar to those of the first preferred embodiment by providing the gas ejection ports 68 in the upper surface of the transport arm 160. Additionally, the second preferred embodiment provides the gas ejection ports 68 in the recessed portion including the indentations 61 or the like and supplies the nitrogen gas to the gas ejection ports 68, to expel the ambient atmosphere remaining in the recessed portion, thereby preventing the ambient atmosphere from being brought into the chamber 15. This more reliably inhibits the increase in oxygen concentration within the chamber 15 to consequently achieve the efficient formation of the interlayer insulation film having a low dielectric constant by firing.

### 3. Third Preferred Embodiment

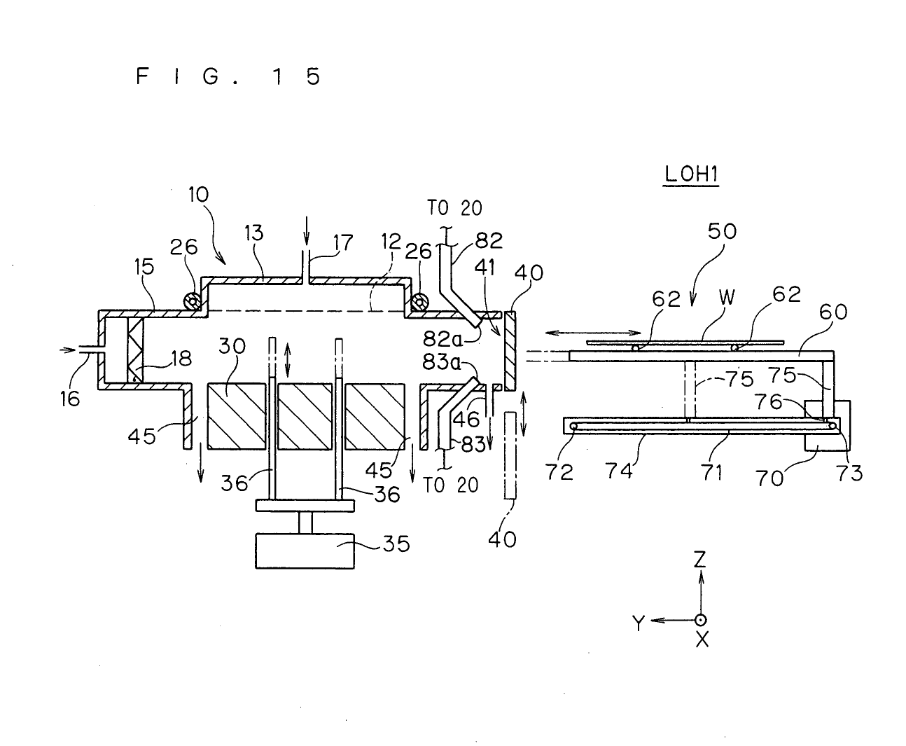

FIG. 14 is a side sectional view of the heat treatment apparatus LOH1 according to a third preferred embodiment of the present invention. Many of the constituents of the units of the substrate processing apparatus of the third preferred embodiment are similar to those of the substrate processing apparatus of the first preferred embodiment. These constituents in the third preferred embodiment are designated by reference numerals and characters identical with those in the first preferred embodiment, and will not be described.

In the substrate processing apparatus according to the third preferred embodiment, as shown in FIG. 14, a gas ejection nozzle 81 for ejecting nitrogen gas is supported by a support element not shown and fixedly provided in the heat treatment apparatus LOH1. The gas ejection nozzle 81 is positioned over the transport arm 60 located in its standby position so as not to interfere with the load/unload unit 50, the standby position of the transport arm 60 being a position in which the transport arm 60 is on standby in opposed relation to the opening 41 of the chamber 15. The gas ejection nozzle 81 is connected in communication with the nitrogen gas supply unit 20 through gas supply piping not shown, and a valve controlled to open and close by the controller CR is inserted in the gas supply piping. The gas ejection nozzle 81 includes a circular gas ejection port 81a formed to face toward a gap between the transport arm 60 located in its standby position and the substrate W held by the transport arm 60. Thus, when the transport arm 60 which holds the substrate W is in the standby position, the gas ejection nozzle 81 can eject the nitrogen gas toward the transport arm 60 and the substrate W to blow the nitrogen gas into the space between the substrate W and the transport arm 60, thereby expelling the ambient atmosphere between the substrate W and the transport arm 60 from the space therebetween and thereby providing a nitrogen gas atmosphere surrounding the entire transport arm 60. Other apparatus structures and substrate processing operation in the third preferred embodiment are identical with those of the first preferred embodiment. As in the first preferred embodiment, a plurality of gas ejection ports 68 may be formed in the transport arm 60.

According to the third preferred embodiment, the ambient atmosphere in the gap between the substrate W and the transport arm 60 is replaced with the nitrogen gas atmosphere before the substrate W is transported into the chamber 15. Additionally, the entire transport arm 60 is surrounded by the nitrogen gas atmosphere. Thus, the transport arm 60 is significantly prevented from bringing the ambient atmosphere into the chamber 15. This reliably inhibits the increase in oxygen concentration within the chamber 15 to consequently achieve the efficient formation of the interlayer insulation film having a low dielectric constant by firing.

Additionally, the third preferred embodiment can inhibit the increase in oxygen concentration within the chamber 15 even if a small amount of nitrogen gas is supplied for the formation of a gas flow by the gas inlet 16 when the substrate W is transported into the chamber 15, thereby to inhibit the increase in consumption of the nitrogen gas.

### 4. Fourth Preferred Embodiment

FIG. 15 is a side sectional view of the heat treatment apparatus LOH1 according to a fourth preferred embodiment of the present invention. Many of the constituents of the units of the substrate processing apparatus of the fourth preferred embodiment are similar to those of the substrate processing apparatus of the first preferred embodiment. These constituents in the fourth preferred embodiment are designated by reference numerals and characters identical with those in the first preferred embodiment, and will not be described.

As shown in FIG. 15, the substrate processing apparatus according to the fourth preferred embodiment includes gas ejection nozzles 82 and 83 similar to the gas ejection nozzle 81 of the third preferred embodiment in upper and lower surfaces, respectively, of the chamber 15 of the heating unit 10 near the opening 41. Like the gas ejection nozzle 81, each of the gas ejection nozzles 82 and 83 is connected in communication with the nitrogen gas supply unit 20 through gas supply piping not shown, and a valve controlled to open and close by the controller CR is inserted in the gas supply piping. The gas ejection nozzles 82 and 83 include respective circular gas ejection ports 82a and 83a formed to face toward the opening 41. Thus, when the transport arm 60 which holds the substrate W transports the substrate W into the chamber 15, the gas ejection nozzles 82 and 83 can eject the nitrogen gas toward the transport arm 60 and the substrate W to provide a nitrogen gas atmosphere surrounding the transport arm 60. Other apparatus structures and substrate processing operation in the fourth preferred embodiment are identical with those of the first preferred embodiment. As in the first preferred embodiment, a plurality of gas ejection ports 68 may be formed in the transport arm 60.

The fourth preferred embodiment provides the nitrogen gas atmosphere enveloping the entire transport arm 60 when the substrate W is transported into the chamber 15. Thus, the transport arm 60 is significantly prevented from bringing the ambient atmosphere into the chamber 15. This reliably inhibits the increase in oxygen concentration within the chamber 15 to consequently achieve the efficient formation of the interlayer insulation film having a low dielectric constant by firing.

Additionally, the fourth preferred embodiment can inhibit the increase in oxygen concentration within the chamber 15 even if a small amount of nitrogen gas is supplied for the formation of a gas flow by the gas inlet 16 when the substrate W is transported into the chamber 15, thereby to inhibit the increase in consumption of the nitrogen gas. In other words, the gas ejection from the gas ejection nozzles 82 and 83 also has the function of assisting the gas ejection from the gas inlet 16.

5. Modifications

The preferred embodiments according to the present invention have been described above. The present invention, however, is not limited to the above examples.

For example, the number, configuration and arrangement of gas ejection ports and the like are not limited to those described in the above-mentioned preferred embodiments. As an example, the arrangement of the gas ejection ports 68 in the first preferred embodiment is not limited to that shown in FIG. 3. However, the number and arrangement of gas ejection ports 68 are preferably adapted so that the areas of the substrate W covered with the nitrogen gas ejected from the respective gas ejection ports 68 are approximately equal to each other.

Although the gas ejection ports 68 are provided in the front surface and recessed portion of the transport arm 160 in the second preferred embodiment, the gas ejection ports 68 may be provided in the back surface and side surface of the transport arm 160. Such a modification enables the nitrogen gas atmosphere to surround the entire transport arm 160, thereby producing effects similar to those of the third and fourth preferred embodiments.

The gas ejection nozzle 81 is provided over the transport arm 60 located in the standby position according to the third preferred embodiment, and the gas ejection nozzles 82 and 83 are provided in the upper and lower surfaces of the chamber 15 of the heating unit 10 near the opening 41 according to the fourth preferred embodiment. These gas ejection nozzles may be arranged in any position at least near the path of movement of the transport arm 60 extending from near the standby position of the transport arm 60 to near the opening 41 of the chamber 15. All of the gas ejection nozzles 81, 82 and 83 according to the third and fourth preferred embodiments may be provided. Such a modification further prevents the ambient atmosphere from being brought into the chamber 15 to more reliably inhibit the increase in oxygen concentration within the chamber 15. Further, the heat treatment apparatus LOH1 provided with all of the gas ejection nozzles 81, 82 and 83 may include the transport arm 60 provided with the gas ejection ports 68 illustrated in the second preferred embodiment in the upper surface and the recessed portion thereof. Such a modification more reliably inhibits the increase in oxygen concentration within the chamber 15. The gas ejection ports in the above-mentioned preferred embodiments are circular in shape, but may be of an elliptical shape, a quadrilateral shape or the like.

The supply of the nitrogen gas through the gas ejection ports is started several seconds before the start of the operation of the transport arm 60, and is stopped when the transport arm 60 exits from the chamber 15, in the above-mentioned preferred embodiments. However, the ejection of the nitrogen gas may be started at any time at least before the substrate W is transported into the chamber 15, and may be stopped at any time after the start of the ejection. For example, the ejection of the nitrogen gas may be started several seconds before the start of the operation of the transport arm 60 and be stopped immediately before the start of the operation of the transport arm 60. In another example, the ejection of the nitrogen gas may be started during the operation of the transport arm 60 and be stopped when the transport arm 60 is stopped in the chamber 15. To achieve reliable effects, it is desirable to continue the ejection of the nitrogen gas until the transport arm 60 entirely enters the chamber 15.

In the third preferred embodiment, the gas ejection nozzle 81 is fixedly provided over the standby position of the transport arm 60. The gas ejection nozzle 81, however, may be fixedly provided on the transport arm 60 itself or be movable independently of the transport arm 60, in which case the gas ejection nozzle 81 is required to be positioned so as not to interfere with the chamber 15 when the gas ejection nozzle 81 is moved.

Although the nitrogen gas is used in the above-mentioned preferred embodiments, any inert gas containing no oxygen may be used. For example, argon or the like may be used.

While the invention has been described in detail, the foregoing description is in all aspects illustrative and not restrictive. It is understood that numerous other modifications and variations can be devised without departing from the scope of the invention.

1. A heat treatment apparatus for performing heat treatment upon a substrate coated with a processing solution to form a predetermined film on said substrate, said heat treatment apparatus comprising:
a processing chamber for performing said heat treatment upon a substrate;
a nitrogen gas supply part for supplying nitrogen gas into said processing chamber to maintain a low oxygen concentration atmosphere within said processing chamber;
a heating part in said processing chamber for placing thereon said substrate loaded into said processing chamber to heat said substrate;
a loading/unloading part movable into and out of said processing chamber for loading and unloading said substrate into and out of said processing chamber;
a cooling part in said loading/unloading part for cooling said substrate held by said loading/unloading part; and
a first ejection port in said loading/unloading part for ejecting nitrogen gas toward a space between said substrate held by said loading/unloading part and said loading/unloading part.

2. The heat treatment apparatus according to claim 1, further comprising
a second ejection port in a wall surface of a recessed portion formed in said loading/unloading part for ejecting nitrogen gas toward said recessed portion.

3. The heat treatment apparatus according to claim 1, further comprising
a nitrogen gas atmosphere forming part for providing a nitrogen gas atmosphere surrounding said loading/unloading part.

4. The heat treatment apparatus according to claim 3, wherein
said nitrogen gas atmosphere forming part is provided at an opening of said processing chamber through which said loading/unloading part enters said processing chamber.

5. The heat treatment apparatus according to claim 3, wherein
said nitrogen gas atmosphere forming part includes a third ejection port provided at said loading/unloading part for ejecting nitrogen gas toward around said loading/unloading part.

6. A heat treatment apparatus for performing heat treatment upon a substrate coated with a processing solution to form a predetermined film on said substrate, said heat treatment apparatus comprising:
a processing chamber for performing said heat treatment upon a substrate;
a nitrogen gas supply part for supplying nitrogen gas into said processing chamber to maintain a low oxygen concentration atmosphere within said processing chamber;
a heating part in said processing chamber for placing thereon said substrate loaded into said processing chamber to heat said substrate;
a loading/unloading part movable into and out of said processing chamber for loading and unloading said substrate into and out of said processing chamber;
a cooling part in said loading/unloading part for cooling said substrate held by said loading/unloading part; and
an ejection part for ejecting nitrogen gas toward a space between said substrate held by said loading/unloading part and said loading/unloading part.

7. The heat treatment apparatus according to claim 6, wherein
said ejection part further provides a nitrogen gas atmosphere around said loading/unloading part.

8. A heat treatment apparatus for performing heat treatment upon a substrate coated with a processing solution to form a predetermined film on said substrate, said heat treatment apparatus comprising:
a processing chamber for performing said heat treatment upon a substrate;
a nitrogen gas supply part for supplying nitrogen gas into said processing chamber to maintain a low oxygen concentration atmosphere within said processing chamber;
a heating part in said processing chamber for placing thereon said substrate loaded into said processing chamber to heat said substrate;
a loading/unloading part movable into and out of said processing chamber for loading and unloading said substrate into and out of said processing chamber;
a cooling part in said loading/unloading part for cooling said substrate held by said loading/unloading part; and
a plurality of ejection ports in said loading/unloading part for ejecting nitrogen gas toward a space between said substrate held by said loading/unloading part and said loading/unloading part,
wherein said plurality of ejection ports are arranged in said loading/unloading part so that areas of said substrate covered with the nitrogen gas ejected from said plurality of gas ejection ports, respectively, are approximately equal to each other.

9. A substrate processing apparatus for coating a substrate with a processing solution and performing heat treatment upon said substrate to form a predetermined film on said substrate, said substrate processing apparatus comprising:
a) a coating processor for coating a substrate with said processing solution;
b) a heat treatment apparatus including
b-1) a processing chamber for performing said heat treatment upon said substrate,
b-2) a nitrogen gas supply part for supplying nitrogen gas into said processing chamber to maintain a low oxygen concentration atmosphere within said processing chamber,
b-3) a heating part in said processing chamber for placing thereon said substrate loaded into said processing chamber to heat said substrate,
b-4) a loading/unloading part movable into and out of said processing chamber for loading and unloading said substrate into and out of said processing chamber,
b-5) a cooling part in said loading/unloading part for cooling said substrate held by said loading/unloading part, and
b-6) an ejection part for ejecting nitrogen gas toward a space between said substrate held by said loading/unloading part and said loading/unloading part; and
c) a transport part for transporting said substrate between said coating processor and said heat treatment apparatus.

10. The substrate processing apparatus according to claim 9, wherein
said ejection part further provides a nitrogen gas atmosphere around said loading/unloading part.

11. The substrate processing apparatus according to claim 9, wherein
said ejection part includes an ejection port provided in said loading/unloading part.
